(19) United States
(12) Patent Application Publication
(10) Pub. No.: US 2006/0255339 A1
(43) Pub. Date: Nov. 16, 2006

(54) Single-crystalline gallium nitride substrate

(75) Inventors: Changho Lee, Suwon-si (KR); Hae Yong Lee, Gwangmyeong-si (KR); Hyun Min Shin, Seoul (KR); Chong Don Kim, Seongnam-si (KR)

Correspondence Address: MCDERMOTT WILL & EMERY LLP, 600 13TH STREET, N.W., WASHINGTON, DC, 20005-3096, US

(73) Assignee: SAMSUNG CORNING CO., LTD.

(21) Appl. No.: 11/432,502

(22) Filed: May 12, 2006

(30) Foreign Application Priority Data
May 12, 2005 (KR) 10-2005-0039619

(51) Int. Cl. H01L 29/15

(52) U.S. Cl. 257/76

(57) ABSTRACT

The present invention relates to a single-crystalline gallium nitride substrate having an n-doping concentration of about 0.7×10¹⁸ to about 3×10¹⁸/cm³ and a thermal conductivity of at least about 1.5 W/cmK at a room temperature (300 K), and being appropriately applied in manufacturing of a light emitting device.

### CROSS-REFERENCE TO RELATED APPLICATION

The present application claims priority from Korean Patent Application No. 2005-39619, filed on May 12, 2005, in the Korean Intellectual Property Office, the entire disclosure of which is incorporated herein by reference.

### BACKGROUND OF THE INVENTION

1. Field of the Invention

The present invention relates to a single-crystalline gallium nitride substrate. More particularly, the present invention relates to a single-crystalline gallium nitride substrate having high and uniform thermal conductivity and being applicable in manufacturing of a light emitting device.

2. Description of the Related Art

Generally, in a light emitting device, brightness may be improved by increasing internal quantum efficiency, light extraction efficiency and admitting power. When light conversion efficiency of the device does not increase while increasing the admitting power, temperature inside the device may be increased by heat, and degradation or thermal breakdown of the device may occur, and performance of the device may decrease.

Therefore, designing the light emitting device to dissipate heat has been known to be a very important process for improving reliability of the device. In order to improve heat dissipation characteristics of the device, various research such as a finding an optimal packaging material and an optimal structure of the device have been widely investigated. FIG. 1 is a cross-sectional view schematically illustrating a relationship between a thermal conductivity and a degree of light emission at each portion of a light emitting device so as to efficiently dissipate heat of the device to an exterior. Referring to FIG. 1, the thermal conductivity of the light emitting device increases from a top portion of the light emitting device to a bottom portion of the light emitting device. The top portion of the light emitting device corresponds to a light emitting layer, and the bottom portion of the light emitting device corresponds to a fan as shown in FIG. 1. When at least one portion of the light emitting device has excessively low thermal conductivity, heat flow in the light emitting device is blocked, and heat may accumulate in the emitting device.

A substrate having high thermal conductivity is necessary for a driving device requiring a high power. A single-crystalline sapphire substrate, in general, has a conductivity of about 0.35 W/cmK in a direction parallel with a C-axis and about 0.32 W/cmK in a direction parallel with an A-axis. A single-crystalline gallium nitride substrate is more appropriate for the driving device in comparison to the single-crystalline sapphire substrate since the single-crystalline gallium nitride can be grown in homo-epitaxy and has a more thermal conductivity than the single-crystalline sapphire.

Theoretically, the single-crystalline gallium nitride substrate has a thermal conductivity of about 3.36 to about 5.40 W/cmK, however, in actuality, a gallium nitride template and gallium nitride freestanding substrate have been known to have thermal conductivity of about 1.3 to about 2.2 W/cmK. The thermal conductivity of the single-crystalline gallium nitride substrate depends on a dislocation density, an n-doping concentration, a crystal-growing method, and so on (cited reference [(1) E. K. Sichel et al., J. Phys. Chem. Solids, 38, 330 (1977); (2) J. Zou et al., J. Appl. Phys., 92(5), p. 2534 (2002); (3) D. I. Florescu et al., J. Appl. Phys., 88(6), p. 3295 (2000); (4) A. Jezowski et al., Solid State Communications, 128, p. 69 (2003); (5) C. Y. Luo et al., Appl. Phys. Lett., 75(26), p. 4151 (1999); (6) D. I. Florescu et al., Appl. Phys. Lett., 77(10), p. 1464 (2000); (7) V. M. Asnin et al., Appl. Phys. Lett., 75(9), p. 1240 (1999); and (8) D. Kotchetkov et al., Appl. Phys. Lett., 79(26), p. 4316 (2001)]).

The thermal conductivity of the single-crystalline gallium nitride substrate mainly depends on the n-doping concentration. Referring to the cited reference (2), it is disclosed that the thermal conductivity decreases from about 1.77 W/cmK to about 0.86 W/cmK at room temperature (300K) when the n-doping concentration increases from about 10¹⁷ to about 10¹⁸/cm³. Referring to the cited reference (3), it is disclosed that the thermal conductivity decreases from about 1.95 W/cmK to about 0.86 W/cmK at room temperature (300 K) when the n-doping concentration increases from about 10¹⁷ to about 10¹⁸/cm³.

The thermal conductivity of the single-crystalline gallium nitride substrate decreases with an increase of the n-doping concentration as described above, however, the single-crystalline gallium nitride substrate requires the n-doping concentration to be more than a predetermined n-doping concentration since the single-crystalline gallium nitride substrate is manufactured in a vertical-type device that makes ohmic contact to an n-type electrode at a lower portion of the single-crystalline gallium nitride substrate as shown in FIG. 2. The single-crystalline gallium nitride substrate has the n-doping concentration of about 10¹⁶ to about 10¹⁷/cm³ when the single-crystalline gallium nitride substrate does not undergo an n-doping process. When undoped single-crystalline gallium nitride substrate is directly applied to a vertical-type light emitting device, an n-carrier injected to a light emitting layer is insufficient to decrease a light emitting property of the light emitting device. Therefore, the n-doping concentration should be predetermined so that the single-crystalline gallium nitride substrate may be suitably employed for the light emitting device and a lowering of the thermal conductivity of the single-crystalline gallium nitride substrate may be minimized.

Referring to the cited references (2), (6) and (8), the dislocation density is one of the major factors related to the thermal conductivity of the single-crystalline gallium nitride substrate. However, a relationship between the dislocation density and the thermal conductivity has not been completely disclosed.

### SUMMARY OF THE INVENTION

The present invention provides a single-crystalline gallium nitride substrate having sufficiently high and uniform thermal conductivity to be appropriately applied in manufacturing of a semiconductor device such as high-luminescent light emitting device requiring an admitting power of more than about 1 W.

A single-crystalline gallium nitride substrate in accordance with an exemplary embodiment of the present invention has an n-doping concentration of about 0.7×10¹⁸ to about 3×10¹⁸/cm³ and a thermal conductivity of at least about 1.5 W/cmK at a room temperature (300 K).

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a cross-sectional view schematically illustrating a relationship between a thermal conductivity and a degree of light emission at each portion of a light emitting device so as to efficiently dissipate heat of the device to an exterior;

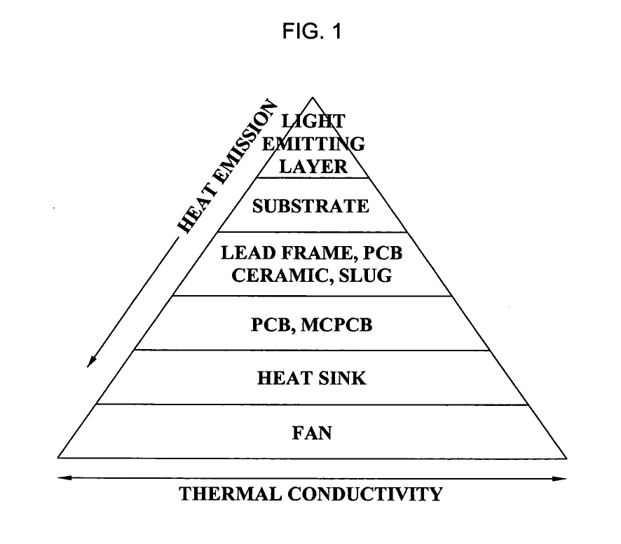

FIG. 2 is a cross-sectional view schematically illustrating a gallium nitride-based vertical-type device employing a single-crystalline gallium nitride substrate in accordance with an exemplary embodiment of the present invention; and

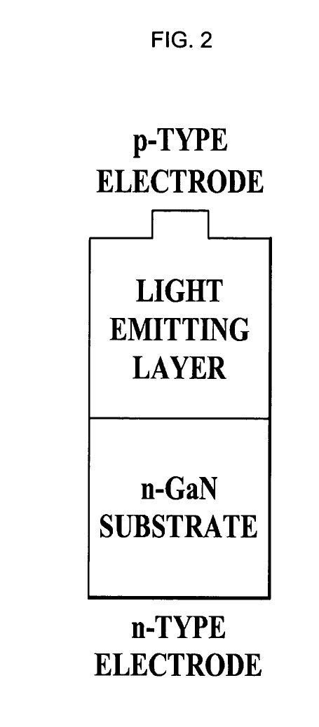

FIG. 3 is a graph illustrating a relationship between a temperature (from 80 K to 400 K) and a thermal conductivity with regard to each of single-crystalline gallium nitride substrates (Example 1, Example 2 and Comparative Example 1).

### DETAILED DESCRIPTION OF THE INVENTION

Hereinafter, the present invention will be described in detail. It should be apparent that the invention may be modified in arrangement and detail without departing from following principles.

Hereinafter, a single-crystalline gallium nitride substrate according to the present invention is described in detail.

A single-crystalline gallium nitride substrate according to the present invention has a minimized n-doping concentration that is possible for manufacturing a light emitting device by using the above single-crystalline gallium nitride substrate. The single-crystalline gallium nitride substrate has a predetermined range of dislocation density, so that the single-crystalline gallium nitride substrate has a thermal conductivity of at least about 1.5 W/cmK, and preferably at least about 1.7 W/cmK.

The single-crystalline gallium nitride substrate is controlled to have an n-doping concentration of about 0.7×10¹⁸ to about 3×10¹⁸/cm³, preferably about 1×10¹⁸ to about 2×10¹⁸/cm³. When the n-doping concentration of the substrate is less than about 0.7×10¹⁸/cm³, an intensity of radiation of a light emitting device employing the single-crystalline gallium nitride substrate is excessively decreases. When the n-doping concentration of the substrate exceeds about 3×10¹⁸/cm³, the thermal conductivity of the single-crystalline gallium nitride substrate decreases to generate degradation in the light emitting device employing the single-crystalline gallium nitride substrate.

A dopant such as silicon (Si), oxygen (O₂), germanium (Ge), carbon (C), etc., is doped into a single-crystalline gallium nitride layer during growth of the single-crystal line gallium nitride on a base substrate. These dopants may be used alone or in a mixture thereof.

The single-crystalline gallium nitride substrate is controlled to have a dislocation density of less than about 7×10⁶/cm² under the range of the n-doping concentration above described. The dislocation density is determined by an experimental method concerning the n-doping concentration. When the dislocation density exceeds about 7×10⁶/cm², the thermal conductivity of the single-crystalline gallium nitride substrate decreases to generate degradation in the light emitting device employing the single-crystalline gallium nitride substrate.

The single-crystalline gallium nitride substrate may be manufactured by a HPVE (hydride vapor phase epitaxy) method. In particularly, the single-crystalline gallium nitride layer is grown by a growing speed of about 10 to 100 μm/hr on a single-crystalline sapphire base substrate heated to be a temperature of about 900 to 1100° C., to thereby completing a single-crystalline template. The completely grown up single-crystalline gallium nitride layer is released from the base substrate and polished, to thereby completing a single-crystalline freestanding substrate.

Sufficient quantity of gallium is disposed in the HVPE reaction container, and then hydro chloride (HCl) gas is reacted with gallium at a temperature of about 600 to about 900° C. to form a gallium chloride (GaCl) gas. An ammonia (NH₃) gas is injected into the HVPE reaction container to react the NH₃ gas with the GaCl gas, thereby forming gallium nitride layer. The HCl gas and the NH₃ gas are respectively provided into the HVPE reaction container by a volume ratio of about 1:2˜6, preferably about 1:3˜4. The volume ratio of the HCl gas and the NH₃ gas and a thickness of the single-crystalline gallium nitride layer are controlled so that the single-crystalline gallium nitride substrate may have the dislocation density that is required in the present invention.

The single-crystalline gallium nitride substrate according to the present invention may have the thickness of at least about 200 μm and a size of at least about 10 mm×10 mm. The single-crystalline gallium nitride substrate has the n-doping concentration of about 0.7×10¹⁸ to about 3×10¹⁸/cm³ through an entirely area of the substrate, and has the thermal conductivity of at least about 1.5 W/cmK, preferably about 1.7 W/cmK at a room temperature (300 K). The thermal conductivity of the substrate is substantially uniform by a variation of about 10%. In addition, the single-crystalline gallium nitride substrate may have a FWHM (full width at half-maximum) value of less than about 150 arcsec, preferably less than about 100 arcsec in accordance with an X-ray diffraction (XRD) rocking curve.

A condition of growing the single-crystalline gallium nitride is properly controlled, so that the single-crystalline gallium nitride substrate preferably has a substantially uniform dislocation density through the entirely area of the substrate.

The single-crystalline gallium nitride substrate according to the present invention may be appropriately applied in manufacturing of a semiconductor device such as high-luminescent light emitting device requiring an admitting power of more than about 1 W. Therefore, the single-crystalline gallium nitride substrate may reduce heat accumulated inside the light emitting device to increase a durability of the light emitting device. A semiconductor device including the single-crystalline gallium nitride substrate according to the present invention, a light emitting layer, and p-type and n-type electrode layers may have an excellent light emitting property and improved endurance property.

Hereinafter, the present invention will be described in detail with reference to following examples. Although a few examples of the present invention are shown in below, the present invention is not limited to the described examples. Instead, it would be appreciated by those skilled in the art that changes may be made to these examples without departing from the principles and spirit of the invention, the scope of which is defined by the claims and their equivalents.

### EXAMPLE 1

Single-crystalline sapphire base substrate having a size of about 10 mm×10 mm was put into a HVPE (hydride vapor phase epitaxy) reaction container, and a sufficient quantity of gallium was disposed in the reaction container. A hydro chloride (HCl) gas was reacted with gallium at a temperature of about 600 to about 900° C. to form a gallium chloride (GaCl) gas. An ammonia (NH₃) gas was injected into the reaction container to react the NH₃ gas with the GaCl gas, thereby forming a single-crystalline gallium nitride layer having a thickness of about 420 μm on the single-crystalline sapphire base substrate. While the single-crystalline gallium nitride layer was formed, the single-crystalline gallium nitride layer was provided with silicon (Si) by a discharge of about 3.5 sccm to be doped with Si. The single-crystalline gallium nitride was grown at a temperature of about 1000° C., and growing speed was about 60 μm/hr. The HCl gas and the NH₃ gas were respectively provided into the reaction container by a volume ratio of about 1:4.

The grown single-crystalline gallium nitride layer was released from the single-crystalline sapphire base substrate by using a Q-switched Nd:YAG eximer laser (355 nm). Then, the released single-crystalline gallium nitride layer was wrapped and polished by using a polishing apparatus at a surface of the layer, to thereby acquiring a gallium nitride freestanding substrate having the n-doping concentration of about 1.3×10¹⁸/cm³, the dislocation density of about 3.6×10⁶/cm² and the thickness of about 287 μm. The dislocation density and the n-doping concentration was measured by using a micro-PL mapping (50×50 μm²) and a hole effect measuring instrument, respectively. The hole effect was measured at a room temperature.

A FWHM (full width at half-maximum) value and the thermal conductivity was measured by using an XRD rocking-curve and a third-harmonic electrical method [C. Y. Luo et al., Appl. Phys. Lett., 75(26), p. 4151 (1999)], respectively. Results are shown in Table 1 below.

### EXAMPLE 2

A single-crystalline gallium nitride layer was grown on a single-crystalline sapphire base substrate to have a thickness of about 360 μm by using a same method as Example 1. While the single-crystalline gallium nitride layer was formed, the single-crystalline gallium nitride layer was provided with silicon (Si) by a discharge of about 3.5 sccm to be doped with Si. The single-crystalline gallium nitride was grown at a temperature of about 1000° C., and growing speed was about 50 μm/hr. The HCl gas and the NH₃ gas were respectively provided into the reaction container by a volume ratio of about 1:3.

The grown single-crystalline gallium nitride layer was released from the single-crystalline sapphire base substrate by using a Q-switched Nd:YAG eximer laser (355 nm). Then, the released single-crystalline gallium nitride layer was wrapped and polished by using a polishing apparatus at a surface of the layer, to thereby acquiring a gallium nitride freestanding substrate having the n-doping concentration of about 1.0×10¹⁸/cm³, the dislocation density of about 6.4×10⁶/cm² and the thickness of about 251 μm. The dislocation density and the n-doping concentration was measured by using a micro-PL mapping and a hole effect measuring instrument, respectively. The hole effect was measured at a room temperature.

A FWHM (full width at half-maximum) value and the thermal conductivity was measured by using an XRD rocking-curve and a third-harmonic electrical method, respectively. Results are shown in Table 1 below.

### COMPARATIVE EXAMPLE 1

A single-crystalline gallium nitride layer was grown on a single-crystalline sapphire base substrate to acquire a single-crystalline gallium nitride template having a thickness of about 50 μm, an n-doping concentration of about 1.0×10¹⁸/cm³ and a dislocation density of about 6.4×10⁶/cm² by using a same method as Example 1. While the single-crystalline gallium nitride layer was formed, the single-crystalline gallium nitride layer was provided with silicon (Si) by a discharge of about 3.5 sccm to be doped with Si. The single-crystalline gallium nitride was grown at a temperature of about 1000° C., and growing speed was about 40 μm/hr. The HCl gas and the NH₃ gas were respectively provided into the reaction container by a volume ratio of about 1:2.

The dislocation density and the n-doping concentration of the acquired single-crystalline gallium nitride substrate was measured by using a micro-PL mapping and a hole effect measuring instrument, respectively. The hole effect was measured at a room temperature. The thermal conductivity of the single-crystalline gallium nitride substrate was measured by using the third-harmonic electrical method. Results are shown in Table 1 below.

TABLE 1

| | n-doping | Dislocation | | Thermal |
|---|---|---|---|---|
| | concentration | density | FWHM | conductivity at |
| Item | (/cm³) | (/cm³) | (arcsec) | 300 K (W/cmK) |
| Example 1 | 1.3 × 10¹⁸ | 3.6 × 10⁶ | 79 | 1.85 |
| Example 2 | 1.0 × 10¹⁸ | 6.4 × 10⁶ | 90 | 1.76 |
| Comparative | 0.9 × 10¹⁸ | 1.0 × 10⁸ | | 1.3 |
| Example 1 | | | | |

Referring to Table 1, the single-crystalline gallium nitride substrates of Example 1 and 2, which satisfy at the n-doping concentration and the dislocation density according to the present invention have an excellent thermal conductivity in comparison to the single-crystalline gallium nitride substrate of Comparative Example 1.

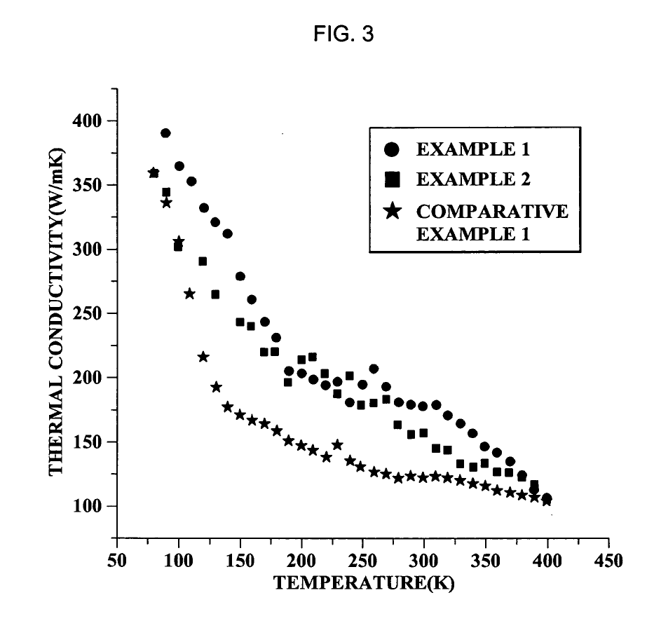

FIG. 3 is a graph illustrating a relationship between a temperature (from 80 K to 400 K) and a thermal conductivity with regard to each of single-crystalline gallium nitride substrates (Example 1, Example 2 and Comparative Example 1). Referring to FIG. 3, the single-crystalline gallium nitride substrates of Example 1 and 2 have an excellent thermal conductivity at an entirely temperature of from about 80 K to about 400 K.

According to the present invention, the single-crystalline gallium nitride substrate having sufficiently high and uniform thermal conductivity to be appropriately applied in manufacturing of a semiconductor device such as high-luminescent light emitting device requiring an admitting power of more than about 1 W. Therefore, the single-crystalline gallium nitride substrate may reduce heat accumulated inside the light emitting device to increase a durability of the light emitting device.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A single-crystalline gallium nitride substrate having an n-doping concentration of about 0.7×10¹⁸ to about 3×10¹⁸/cm³ and a thermal conductivity of at least about 1.5 W/cmK at a room temperature.

2. A single-crystalline gallium nitride substrate of claim 1, wherein the single-crystalline gallium nitride substrate has the thermal conductivity of at least about 1.7 W/cmK at a room temperature.

3. A single-crystalline gallium nitride substrate of claim 1, wherein the single-crystalline gallium nitride substrate has a dislocation density of less than about 7×10⁶/cm².

4. A single-crystalline gallium nitride substrate of claim 1, wherein the single-crystalline gallium nitride substrate has the n-doping concentration of about 1×10¹⁸ to about 2×10¹⁸/cm³.

5. A single-crystalline gallium nitride substrate of claim 1, wherein a FWHM value according to an XRD rocking curve is less than about 150 arcsec.

6. A single-crystalline gallium nitride substrate of claim 1, wherein the single-crystalline gallium nitride substrate is formed by growing a single-crystalline gallium nitride on a single-crystalline sapphire base substrate.

7. A single-crystalline gallium nitride substrate of claim 6, wherein the single-crystalline gallium nitride substrate includes a polished surface.

8. A single-crystalline gallium nitride substrate of claim 1, wherein the single-crystalline gallium nitride is grown by using a hydride vapor phase epixaxy (HVPE).

9. A single-crystalline gallium nitride substrate of claim 1, wherein the single-crystalline gallium nitride substrate has a thickness of at least about 200 μm.

10. A single-crystalline gallium nitride substrate of claim 1, wherein the single-crystalline gallium nitride substrate has a size of at leas about 10 mm×10 mm.

11. A single-crystalline gallium nitride substrate of claim 1, wherein the single-crystalline gallium nitride substrate is used for a freestanding substrate in manufacturing a light emitting device,

12. A single-crystalline gallium nitride substrate of claim 1, wherein the single-crystalline gallium nitride substrate has a substantially uniform dislocation density at an entirely area of the substrate.

13. A semiconductor device comprising the single-crystalline gallium nitride substrate of claim 1, a light emitting layer, and p-type and n-type electrodes.
